(19) United States
(12) Patent Application Publication
(10) Pub. No.: US 2012/0160292 A1
(43) Pub. Date: Jun. 28, 2012

(54) THERMOELECTRIC DEVICE AND MANUFACTURING METHOD THEREOF

(75) Inventors: Moon Gyu JANG, Daejeon (KR); Young Sam Park, Deajeon (KR); Younghoon Hyun, Seoul (KR); Myungsim Jun, Deajeon (KR); Taehyoung Zyung, Daejeon (KR)

(73) Assignee: ELECTRONICS AND TELECOMMUNICATIONS RESEARCH INSTITUTE, Daejeon (KR)

(21) Appl. No.: 13/323,844

(22) Filed: Dec. 13, 2011

(30) Foreign Application Priority Data
Dec. 22, 2010 (KR) 10-2010-0132921

(51) Int. Cl. H01L 35/14; H01L 35/34; H01L 35/32; H01L 37/00

(52) U.S. Cl. 136/236.1; 438/54; 136/200; 136/201; 257/E21.09

(57) ABSTRACT

A thermoelectric device includes: a substrate; a first nanowire of a first conductive type, which is formed on one side of the substrate; a second nanowire of a second conductive type, which is opposed to the first nanowire; a high temperature part commonly connected to one end of the first nanowire and one end of the second nanowire; low temperature parts connected to the other end of the first nanowire and the other end of the second nanowire, respectively; an insulation layer formed on the first nanowire and the second nanowire; a first metal layer formed on a portion of the insulation layer over the first nanowire, so as to control an electric potential of the first nanowire; and a second metal layer formed on a portion of the insulation layer over the second nanowire, so as to control an electric potential of the second nanowire.

### CROSS-REFERENCE TO RELATED APPLICATIONS

This application is based on and claims priority from Korean Patent Application No. 10-2010-0132921, filed on Dec. 22, 2010, with the Korean Intellectual Property Office, the disclosure of which is incorporated herein in its entirety by reference.

### BACKGROUND OF THE INVENTION

1. Field of the Invention

The present invention relates to a thermoelectric device, and more particularly to a thermoelectric device and a manufacturing method thereof, in which an N-type leg and a P-type leg are formed of materials having different work functions, so as to increase the Seebeck coefficient.

2. Description of the Prior Art

The thermoelectric effect was discovered by Thomas Seebeck in the year of 1821 and has been widely applied to industrial fields from the 1950's at which semiconductor materials were found.

Currently, Bi2Te3 is being widely used as materials of thermoelectric devices, and the ZT value of Bi2Te3, which is an index indicating characteristics of the thermoelectric effect, is less than or equal to 1. However, when the ZT value of a thermoelectric device is less than or equal to 1, an energy conversion efficiency of the thermoelectric device from thermal energy to electric energy is smaller than 5%. Therefore, such a low energy conversion efficiency puts many limitations on actual application of the thermoelectric device.

Therefore, in order to apply the thermoelectric device to a refrigerator, etc., it is necessary to develop a thermoelectric semiconductor having a ZT value larger than 3.

In general, ZT is in proportion to the square of Seebeck coefficient. That is, when the Seebeck coefficient becomes a doubled value, ZT becomes a quadrupled value. Therefore, in the case of Bi2Te3, if a technology capable of increasing the Seebeck coefficient to a doubled value is secured, it is possible to satisfy the property of (ZT>3) and to bring an epoch-making development for application products using the thermoelectric devices in the future.

Meanwhile, although there have been sufficient developments in technologies for micro-processing of silicon, which has sufficient resource reserves and is known to be harmless to a human body, it is difficult to use the silicon as a thermoelectric device, because the silicon has a very high thermal conductivity, that is, 150 W/m·K and thus has a ZT value (which is a figure of merit for a thermoelectric device) of only 0.01.

However, there has been a recent report in the journal “Nature” that it is possible to reduce the thermal conductivity of a silicon nanowire developed by a Chemical Vapor Deposition (CVD) up to a value below 0.01 times of that of the conventional silicon, which results in that the silicon nanowire has a ZT value larger than 1. Further, very active researches for new materials for the thermoelectric device are in progress in Berkeley, Harvard, Caltech, etc.

Recently, a technology for manufacturing a thermoelectric device using silicon nanowire by a top-down type semiconductor process is being developed.

In this regard, an embodiment of the present invention provides a structure of a thermoelectric device using silicon nanowire capable of improving a Seebeck coefficient thereof.

### SUMMARY OF THE INVENTION

Accordingly, the present invention has been made to solve the above-mentioned problems occurring in the prior art, and an object of the present invention is to provide a thermoelectric device and a manufacturing method thereof, in which materials having different work functions are partially formed in an N-type leg and a P-type leg, which are basic elements of a thermoelectric device, so as to increase the Seebeck coefficient.

In order to accomplish this object, there is provided a thermoelectric device including: a substrate; a first nanowire of a first conductive type, which is formed on one side of the substrate; a second nanowire of a second conductive type, which is opposed to the first nanowire; a high temperature part commonly connected to one end of the first nanowire and one end of the second nanowire; low temperature parts connected to the other end of the first nanowire and the other end of the second nanowire, respectively; an insulation layer formed on the first nanowire and the second nanowire; a first metal layer formed on a portion of the insulation layer over the first nanowire, so as to control an electric potential of the first nanowire; and a second metal layer formed on a portion of the insulation layer over the second nanowire, so as to control an electric potential of the second nanowire.

In accordance with another aspect of the present invention, there is provided a method for manufacturing a thermoelectric device, including the steps of: forming structures, which includes a first nanowire pattern, a second nanowire pattern, a high temperature part, and a low temperature part, by depositing and patterning a semiconductor layer on a substrate; forming a first nanowire and a second nanowire by ion-implanting a first conductive material and a second conductive material into the first nanowire pattern and the second nanowire pattern; forming an insulation layer on the first nanowire and the second nanowire by depositing and patterning an insulation material on an entire surface of the substrate; forming a first metal layer on a portion of the insulation layer over the first nanowire by depositing and patterning a metal material on an entire surface of the substrate; and forming a second metal layer on a portion of the insulation layer over the second nanowire by depositing and patterning a metal material on an entire surface of the substrate.

### BRIEF DESCRIPTION OF THE DRAWINGS

The above and other objects, features and advantages of the present invention will be more apparent from the following detailed description taken in conjunction with the accompanying drawings, in which:

FIG. 1 is a perspective view illustrating the structure of a thermoelectric device according to an embodiment of the present invention; and

FIGS. 2 to 7 are perspective views for describing the flow of a method of manufacturing a thermoelectric device according to an embodiment of the present invention.

### DETAILED DESCRIPTION OF THE PREFERRED EMBODIMENTS

Hereinafter, preferred embodiments of the present invention will be described with reference to the accompanying drawings. In the following description, a detailed description of known functions and configurations incorporated herein will be omitted when it may make the subject matter of the present invention rather unclear.

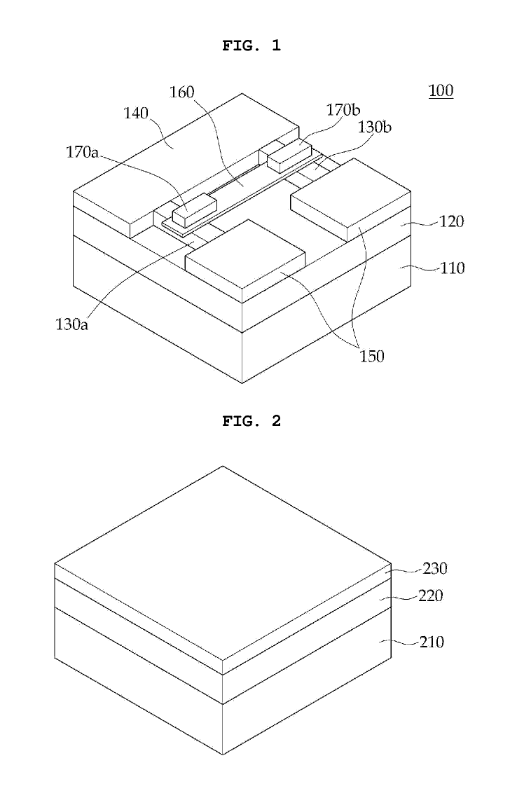

FIG. 1 is a perspective view illustrating the structure of a thermoelectric device according to an embodiment of the present invention.

Referring to FIG. 1, a thermoelectric device 100 according to the present invention includes a substrate 110, an adiabatic layer 120, a first nanowire 130a, a second nanowire 130b, a high temperature part 140, low temperature parts 150, an insulation layer 160, a first metal layer 170a, and a second metal layer 170b.

The substrate 110 supports a plurality of devices and may be a silicon substrate, a glass substrate, a ceramic substrate, a plastic substrate, or an acryl substrate.

The adiabatic layer 120 is formed between the substrate 110 and structures formed on the adiabatic layer 120 and reduces the conduction of the heat generated by the structures to the substrate 110. The adiabatic layer 120 may be formed of a silicon oxide film.

It is preferred that the first nanowire 130a is a first conductive type (i.e. N-type) nanowire, the second nanowire 130b is a second conductive type (i.e. P-type) nanowire, and the first nanowire 130a and the second nanowire 130b are formed and opposed to each other on the adiabatic layer 120. The sectional shape of each of the first nanowire 130a and the second nanowire 130b may be polygonal, circular, ellipsoidal, or fan-shaped.

The high temperature part 140 corresponds to a part for absorbing heat and is connected to both an end of the first nanowire 130a and an end of the second nanowire 130b, and the low temperature parts 150 correspond to parts for discharging heat and are connected to the other end of the first nanowire 130a and the other end of the second nanowire 130b. The high temperature part 140 and the low temperature part 150 may be formed of a silicon film.

The insulation layer 160 is formed between and over the first nanowire 130a and the second nanowire 130b and may include Al₂O₃, HfₓO_{y}, a TEOS-based oxide film, and a nitride film, such as Si₃N₄ or SiN_{X}, which are used as a gate insulation film in a typical CMOS process.

The first metal layer 170a is formed on a portion of the insulation layer 160 above the first nanowire 130a and controls the electric potential of the first nanowire 130a in order to control the electric potential difference between the first nanowire 130a and the second nanowire 130b. To this end, the first metal layer 170a includes materials having a small work function, such as Er, Mg, Yb, Sm, and Eu.

The second metal layer 170b is formed on a portion of the insulation layer 160 above the second nanowire 130b and controls the electric potential of the second nanowire 130b in order to control the electric potential difference between the first nanowire 130a and the second nanowire 130b. To this end, the second metal layer 170b includes materials having a large work function, such as Pt, Mn, and Pd.

Although the first metal layer 170a and the second metal layer 170b are formed of materials having different work functions in the present embodiment, the present invention is not limited to the present embodiment. It is also possible to form the first metal layer 170a and second metal layer 170b from the same material and to apply different voltages to the two metal layers, so as to control the electric potential difference between the first nanowire 130a and the second nanowire 130b.

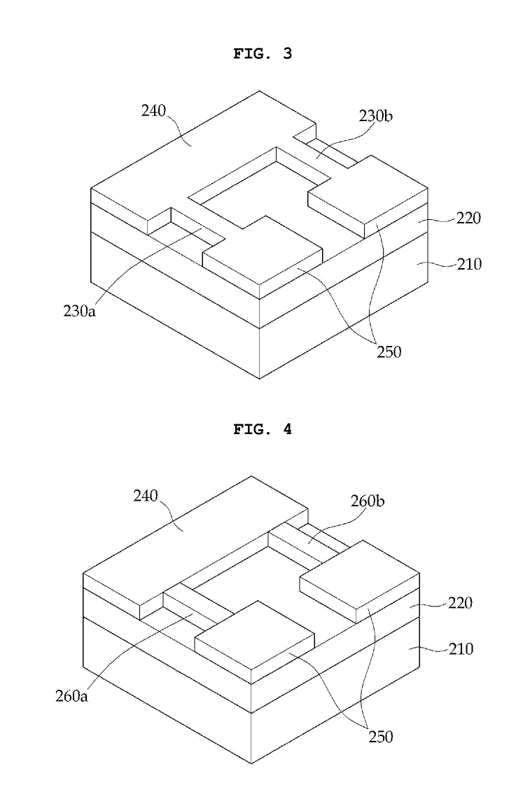

FIGS. 2 to 7 are perspective views for describing the flow of a method of manufacturing a thermoelectric device according to an embodiment of the present invention.

Referring to FIG. 2, an adiabatic layer 220 and a semiconductor layer 230 are sequentially deposited on a substrate 210. The adiabatic layer 220 may be formed of a silicon oxide film and a semiconductor layer 230 may be formed of a silicon film.

Referring to FIG. 3, a first nanowire pattern 230a, a second nanowire pattern 230b, a high temperature part 240, and low temperature parts 250 are formed by patterning the semiconductor layer 230. The first nanowire pattern 230a and the second nanowire pattern 230b are opposed to each other. Further, one end of the first nanowire pattern 230a and one end of the second nanowire pattern 230b are commonly connected to the high temperature part 240, and the other end of the first nanowire pattern 230a and the other end of the second nanowire pattern 230b are connected to the low temperature parts 250.

Referring to FIG. 4, a first conductive material (that is, N-type conductive material) is ion-implanted into the first nanowire pattern 230a and a second conductive material (that is, P-type conductive material) is ion-implanted into the second nanowire pattern 230b, so as to form a first nanowire 260a and a second nanowire 260b.

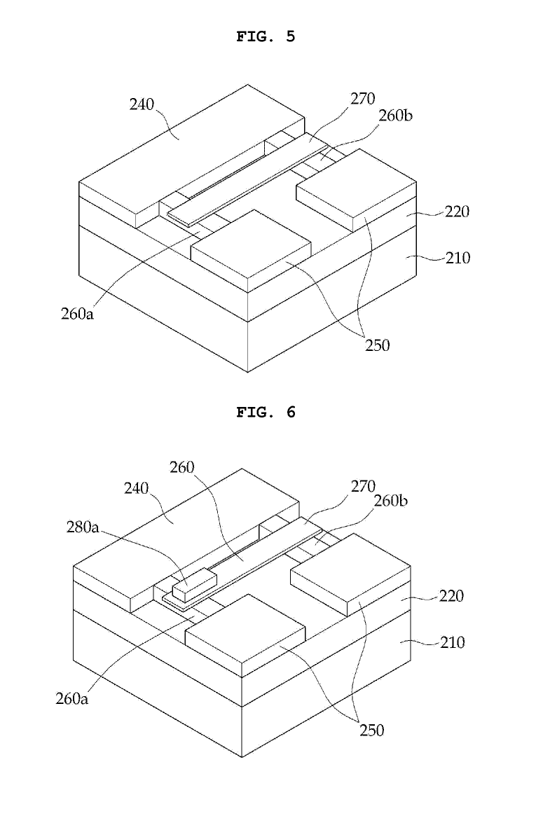

Referring to FIG. 5, an insulation layer 270 extending between and over the first nanowire 260a and the second nanowire 260b is formed by depositing and then patterning an insulation material on an entire surface of the substrate 210 including the first nanowire 260a and the second nanowire 260b. The insulation layer 270 may include Al₂O₃, HfₓO_{y}, a TEOS-based oxide film, and a nitride film, such as Si₃N₄ or SiN_{X}, which are used as a gate insulation film in a typical CMOS process.

Referring to FIG. 6, a first metal layer 280a is formed on a portion of the insulation layer 270 over the first nanowire 260a by depositing and patterning a metal material on an entire surface of the substrate 210 including the insulation layer 270. The first metal layer 280a includes materials having a small work function, such as Er, Mg, Yb, Sm, and Eu. These materials are highly apt to be oxidized and thus may be formed in the form of an alloy.

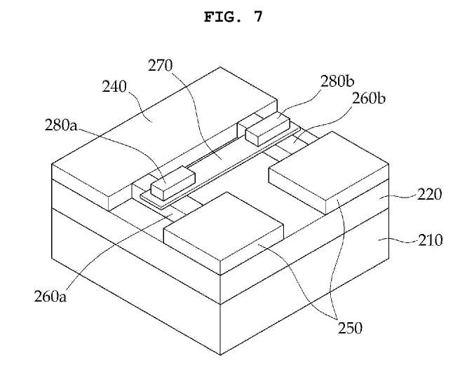

Referring to FIG. 7, a second metal layer 280b is formed on a portion of the insulation layer 270 over the second nanowire 260b by depositing and patterning a metal material on an entire surface of the substrate 210 including the insulation layer 270. The second metal layer 280b includes materials having a large work function, such as PT, Mn, and Pd. These materials are highly apt to be oxidized and thus may be formed in the form of an alloy.

The present invention as described above provides a thermoelectric device and a manufacturing method thereof, in which an N-type leg and a P-type leg are formed of materials having different work functions, which can implement the same effect as that of a voltage applied from the outside, so as to increase the Seebeck voltage of each leg and to thus increase the ZT value, thereby improving the efficiency of the thermoelectric device.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A thermoelectric device comprising:
a substrate;
a first nanowire of a first conductive type, which is formed on one side of the substrate;
a second nanowire of a second conductive type, which is opposed to the first nanowire;
a high temperature part commonly connected to one end of the first nanowire and one end of the second nanowire;
low temperature parts connected to the other end of the first nanowire and the other end of the second nanowire, respectively;
an insulation layer formed on the first nanowire and the second nanowire;
a first metal layer formed on a portion of the insulation layer over the first nanowire, so as to control an electric potential of the first nanowire; and
a second metal layer formed on a portion of the insulation layer over the second nanowire, so as to control an electric potential of the second nanowire.

2. The thermoelectric device as claimed in claim 1, wherein the first metal layer and the second metal layer are formed of materials having different work functions.

3. The thermoelectric device as claimed in claim 1, wherein the first metal layer comprises at least one of Er, Mg, Yb, Sm, and Eu.

4. The thermoelectric device as claimed in claim 1, wherein the second metal layer comprises at least one of Pt, Mn, and Pd.

5. The thermoelectric device as claimed in claim 1, wherein the insulation metal layer comprises at least one of Al₂O₃, HfₓO_{y}, a TEOS-based oxide film, and a nitride film, including Si₃N₄ and SiNₓ.

6. The thermoelectric device as claimed in claim 1, further comprising an adiabatic layer formed between the substrate and structures formed on the adiabatic layer, so as to reduce conduction of heat generated by the structures to the substrate.

7. The thermoelectric device as claimed in claim 1, wherein, when the first metal layer and the second metal layer are formed of an identical material, different voltages are applied to the first metal layer and the second metal layer.

8. A method for manufacturing a thermoelectric device, comprising:
forming structures, which includes a first nanowire pattern, a second nanowire pattern, a high temperature part, and a low temperature part, by depositing and patterning a semiconductor layer on a substrate;
forming a first nanowire and a second nanowire by ion-implanting a first conductive material and a second conductive material into the first nanowire pattern and the second nanowire pattern;
forming an insulation layer on the first nanowire and the second nanowire by depositing and patterning an insulation material on an entire surface of the substrate;
forming a first metal layer on a portion of the insulation layer over the first nanowire by depositing and patterning a metal material on an entire surface of the substrate; and
forming a second metal layer on a portion of the insulation layer over the second nanowire by depositing and patterning a metal material on an entire surface of the substrate.

9. The method as claimed in claim 8, further comprising a step of forming an adiabatic layer for reducing heat conduction between the substrate and structures formed on the adiabatic layer.

10. The method as claimed in claim 8, wherein the first metal layer and the second metal layer are formed of materials having different work functions.

11. The method as claimed in claim 8, wherein the first metal layer comprises at least one of Er, Mg, Yb, Sm, and Eu.

12. The method as claimed in claim 8, wherein the second metal layer comprises at least one of Pt, Mn, and Pd.

13. The method as claimed in claim 8, wherein the insulation metal layer comprises at least one of Al₂O₃, HfₓO_{y}, a TEOS-based oxide film, and a nitride film, including Si₃N₄ and SiNₓ.

14. The method as claimed in claim 8, wherein, in forming the first metal layer and the second metal layer, the first metal layer and the second metal layer are formed of an alloy.
